(19) United States
(12) Patent Application Publication
(10) Pub. No.: US 2021/0066567 A1
(43) Pub. Date: Mar. 4, 2021

(54) MAGNETIC ALLOY MATERIAL

(71) Applicant: NEC CORPORATION, Tokyo (JP)

(72) Inventors: Yasutomo OMORI, Tokyo (JP); Akihiro KIRIHARA, Tokyo (JP); Yuma IWASAKI, Tokyo (JP); Masahiko ISHIDA, Tokyo (JP); Koichi TERASHIMA, Tokyo (JP); Hiroko SOMEYA, Tokyo (JP); Sadanori HATTORI, Tokyo (JP)

(73) Assignee: NEC CORPORATION, Tokyo (JP)

(21) Appl. No.: 17/007,124

(22) Filed: Aug. 31, 2020

(30) Foreign Application Priority Data
Sep. 2, 2019 (JP) 2019-159357

(51) Int. Cl. H01L 35/20; H01L 35/32; H01F 1/147; C22C 38/06; C22C 38/00

(52) U.S. Cl. CPC H01L 35/20; H01L 35/32; C22C 2202/02; C22C 38/06; C22C 38/005; H01F 1/147

(57) ABSTRACT

A magnetic alloy material according to the present disclosure is an iron-aluminum-terbium based magnetic alloy material containing a total of 70 atomic percent or more of three elements of iron, aluminum, and terbium.

This application is based upon and claims the benefit of priority from Japanese Patent Application No. 2019-159357, filed on Sep. 2, 2019, the disclosure of which is incorporated herein in its entirety by reference.

### TECHNICAL FIELD

The present invention relates to a magnetic alloy material used in thermoelectric conversion.

### BACKGROUND ART

As one of heat management techniques aimed at a sustainable society, expectations are running high for thermoelectric conversion. Heat is collectable energy in various scenes, such as body heat, solar heat, and industrial exhaust heat. Thus, thermoelectric conversion is expected to be applied for various uses such as enhanced efficiency of energy use, electric supply to a portable terminal, a sensor, and the like, and visualization of a heat flow by heat flow sensing.

Patent Literature 1 (Japanese Unexamined Patent Application Publication No. 2004-119647), Patent Literature 2 (Japanese Unexamined Patent Application Publication No. 2004-253618), Patent Literature 3 (Japanese Unexamined Patent Application Publication No. 2008-021982), and Patent Literature 4 (Japanese Unexamined Patent Application Publication No. 2006-278784) disclose a thermoelectric conversion element including an iron-vanadium-aluminum (FeVAl) based compound having a Heusler structure. In the thermoelectric conversion element in Patent Literatures 1 to 4, a positive hole and an electron move along a direction of a temperature difference by providing the temperature difference between both main surfaces, and a Seebeck effect in which an electromotive force is generated between both terminals appears.

In recent years, a thermoelectric conversion element including a magnetic material that converts an applied temperature gradient into a current has been developed. A magnetic material in which an anomalous Nernst effect or a spin Seebeck effect appears by a temperature gradient is used for such a thermoelectric conversion element.

A thermoelectric conversion element in which the anomalous Nernst effect appears includes a magnetic metal being magnetized in one direction. When a temperature gradient is applied to the magnetic material in which the anomalous Nernst effect appears, a heat flow generated by the temperature gradient is converted into a current in the magnetic metal. At this time, a direction of a current generated by the anomalous Nernst effect is orthogonal to both of a magnetization direction and a temperature gradient direction. With this characteristic, the thermoelectric conversion element using the anomalous Nernst effect has a simpler element structure than that of an element using the Seebeck effect, and thus application for various uses can be expected.

Non Patent Literature 1 (M. Mizuguchi, S. Ohata, K. Uchida, E. Saitoh, and K. Takanashi, “Anomalous Nernst Effect in an L10-Ordered Epitaxial FePt Thin Film”, Appl. Phys. Express 5 093002 (2012)) discloses an iron-platinum (FePt) alloy including platinum having a great spin orbit interaction as a magnetic material in which the anomalous Nernst effect appears. Non Patent Literature 2 (S. Isogami, T. Takanashi, and M. Mizuguchi, “Dependence of anomalous Nernst effect on crystal orientation in highly ordered γ′-Fe₄N films with anti-perovskite structure”, Appl. Phys. Express 10, 073005 (2017)) discloses an iron nitride (γ′-Fe₄N) based material and an iron-aluminum (Fe₈₀Al₂₀) based alloy material as a magnetic material in which the anomalous Nernst effect appears. When each of the magnetic materials in Non Patent Literatures 1 to 2 is film-formed on a non-magnetic substrate, a thin film element including a thin film crystal of a ferromagnetic material can be formed.

The thermoelectric conversion element using the spin Seebeck effect has a two-layer structure including a magnetic insulating layer having magnetization in one direction and an electromotive body layer having conductivity. When a temperature gradient is applied in an out-of-plane direction of the thermoelectric conversion element using the spin Seebeck effect, a flow of a spin angular momentum, which is called a spin current, is induced in a magnetic insulator by the spin Seebeck effect. When the spin current induced in the magnetic insulator is injected in the electromotive body layer, a current flows in an in-plane direction in an electromotive film by an inverse spin Hall effect. Since the thermoelectric conversion element using the spin Seebeck effect is formed by using the magnetic insulator having relatively small thermal conductivity, a temperature difference for performing effective thermoelectric conversion can be maintained.

Patent Literature 5 (International Publication No. WO2009/151000) and Non Patent Literature 3 (K. Uchida, T. Nonaka, T. Ota, and E. Saitoh, “Longitudinal spin-Seebeck effect in sintered polycrystalline (Mn, Zn) Fe₂O₄”, Appl. Phys. Lett. 97, 262504 (2010)) disclose a thermoelectric conversion element using the spin Seebeck effect. Patent Literature 5 discloses the thermoelectric conversion element including single crystal yttrium gallium iron garnet (hereinafter, described as YIG) as a magnetic insulating layer and a platinum wire as an electromotive body layer. Non Patent Literature 3 discloses the thermoelectric conversion element including a sintering body of polycrystalline manganese-zinc (MnZn) ferrite as a magnetic insulating layer and a platinum thin film as an electromotive body layer.

Non Patent Literature 4 (B. Miao, S. Huang, D. QU, and C. Chien, “Inverse Spin Hall Effect in a Ferromagnetic Metal”, Phys. Rev. Lett. 111, 066602 (2013)) discloses a hybrid-type spin thermoelectric element that uses both the spin Seebeck effect and the anomalous Nernst effect. Both of the spin Seebeck effect and the anomalous Nernst effect have similar symmetry that an electromotive force in the in-plane direction is induced by a temperature gradient in the out-of-plane direction, and thus thermoelectric conversion efficiency can be improved by combining the two effects.

Patent Literature 6 (Japanese Unexamined Patent Application Publication No. 2002-190145) discloses a multilayer film in which a first magnetic layer, a second magnetic layer, and a third magnetic layer are laminated in order. In the multilayer film in Patent Literature 6, a Curie temperature of the second magnetic layer is set lower than a Curie temperature of the first magnetic layer and the third magnetic layer, and the third magnetic layer is set as a perpendicular magnetization film. In a temperature range less than the Curie temperature of the second magnetic layer, the first magnetic layer is perpendicularly magnetized by exchange-coupling to the second magnetic layer, and magnetization of the third magnetic layer is transferred, via exchange coupling, to the first magnetic layer via the second magnetic layer. The second magnetic layer is an in-plane magnetization film at a room temperature, and becomes a perpendicular magnetization film in a temperature range between a critical temperature higher than the room temperature and the Curie temperature of the second magnetic layer.

As in Patent Literature 5 and Non Patent Literatures 1 to 4, the thermoelectric conversion element using the anomalous Nernst effect or the spin Seebeck effect has thermoelectric conversion efficiency lower than that of a general thermoelectric conversion element using the Seebeck effect, and thus a further improvement in thermoelectric conversion efficiency is required for practical use. For example, Non Patent Literature 2 describes that a relatively great anomalous Nernst effect is acquired when an atomic composition ratio of iron to aluminum is 8:2, but does not disclose a composition in which the anomalous Nernst effect is maximum.

### SUMMARY

An object of the present invention is to solve the problem described above, and provide a magnetic alloy material having an anomalous Nernst effect greater than that of a general magnetic alloy material, and having great thermoelectric conversion efficiency.

A magnetic alloy material according to one aspect of the present invention is an iron-aluminum-terbium based magnetic alloy material containing a total of 70 atomic percent or more of three elements of iron, aluminum, and terbium.

### BRIEF DESCRIPTION OF THE DRAWINGS

Exemplary features and advantages of the present invention will become apparent from the following detailed description when taken with the accompanying drawings in which:

FIG. 1 is a schematic diagram illustrating one example of a thermoelectric conversion element according to a first example embodiment;

FIG. 2 is a schematic diagram illustrating one example of a thermoelectric conversion element according to a second example embodiment;

FIG. 3 is a schematic diagram illustrating one example of a thermoelectric conversion element according to a third example embodiment;

FIG. 4 is a schematic diagram illustrating one example of a structure of an iron-aluminum-terbium alloy network included in the thermoelectric conversion element according to the third example embodiment;

FIG. 5 is a schematic diagram illustrating one example of a thermoelectric conversion module according to a fourth example embodiment;

FIG. 6 is a schematic diagram illustrating one example of directions of a heat flow, an electromotive force, and magnetization in the thermoelectric conversion module according to the fourth example embodiment;

FIG. 7 is a schematic diagram illustrating one example of a thermoelectric conversion element according to Example 1;

FIG. 8 is a graph illustrating dependence, on a material composition, of a standardized thermoelectric coefficient of a magnetic alloy material (iron-aluminum-terbium based alloy) measured by using the thermoelectric conversion element according to Example 1;

FIG. 9 is a schematic diagram illustrating one example of a thermoelectric conversion element according to Example 2;

FIG. 10 is a graph illustrating dependence, on a magnetic field, of a heat electromotive force of a magnetic alloy material (iron-aluminum-terbium based alloy) used for the thermoelectric conversion element according to Example 2;

FIG. 11 is a graph in which the heat electromotive force of the iron-aluminum-terbium based alloy used for the thermoelectric conversion element according to Example 2 is compared with a heat electromotive force of an iron-aluminum based alloy; and

FIG. 12 is a schematic diagram illustrating one example of a thermoelectric conversion module according to Example 3.

### EXAMPLE EMBODIMENT

Example embodiments of the present invention will be described below with reference to the drawings. In the following example embodiments, technically preferable limitations are imposed to carry out the present invention, but the scope of this invention is not limited to the following description. In all drawings used to describe the following example embodiments, the same reference numerals denote similar parts unless otherwise specified. In addition, in the following example embodiments, a repetitive description of similar configurations or arrangements and operations may be omitted.

In the example embodiments below, a thermoelectric conversion element using, for a power generation body, an iron-aluminum-terbium based (FeAlTb based) alloy material with iron (Fe), aluminum (Al), and terbium (Tb) as main components will be described. The FeAlTb based alloy material indicated in the example embodiments below achieves thermoelectric conversion efficiency higher than that of an iron-terbium based (FeTb based) alloy material without using aluminum and an iron-aluminum based (FeAl based) alloy material without using terbium. Further, the FeAlTb based alloy material indicated in the example embodiment below achieves thermoelectric conversion efficiency higher than that of an iron-platinum based (FePt based) alloy material including platinum (Pt) and a cobalt-platinum based (CoPt based) alloy material.

### First Example Embodiment

First, a thermoelectric conversion element according to a first example embodiment will be described with reference to a drawing. The thermoelectric conversion element according to the present example embodiment includes a power generation body including an iron-aluminum-terbium alloy (hereinafter, referred to as an FeAlTb alloy) with iron (Fe), aluminum (Al), and terbium (Tb) as main components.

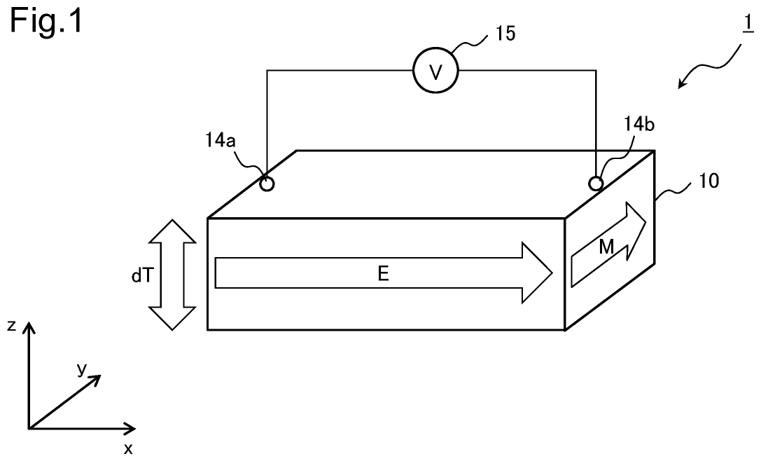

FIG. 1 is a schematic diagram illustrating one example of a thermoelectric conversion element 1 according to the present example embodiment. The thermoelectric conversion element 1 includes a power generation body 10 including an FeAlTb alloy. FIG. 1 illustrates an example in which an electrode terminal 14a and an electrode terminal 14b are installed on one of main surfaces of the power generation body 10, and a voltmeter 15 is installed between the electrode terminal 14a and the electrode terminal 14b. Note that the voltmeter 15 is not included in the configuration of the thermoelectric conversion element 1 according to the present example embodiment. Hereinafter, a direction parallel to the main surface of the power generation body 10 is referred to as an in-plane direction, and a direction perpendicular to the main surface of the power generation body 10 is referred to as an out-of-plane direction.

The thermoelectric conversion element 1 includes the power generation body 10 including the FeAlTb alloy with Fe, Al, and Tb as main components. The FeAlTb alloy is a ferromagnetic body, and includes magnetization M in the in-plane direction (y direction in FIG. 1).

When a temperature gradient dT is applied to the out-of-plane direction (z direction in FIG. 1) of the power generation body 10, an electromotive force E is generated in the in-plane direction (x direction in FIG. 1) perpendicular to a direction of each of the magnetization M and the temperature gradient dT due to an anomalous Nernst effect. Thermoelectric conversion can be achieved by extracting, as electricity, the electromotive force E in the in-plane direction (x direction in FIG. 1) perpendicular to the direction of each of the magnetization M and the temperature gradient dT from between the electrode terminal 14a and the electrode terminal 14b.

The power generation body 10 includes the FeAlTb alloy having a content of three elements of Fe, Al, and Tb being equal to or more than 70 atomic percent (at %). For example, in the three elements of Fe, Al, and Tb, it is preferable that a composition ratio of Al is equal to or more than 20 at % and equal to or less than 35 at %, and a composition ratio of Tb is equal to or more than 5 at % and equal to or less than 20 at %. Note that the FeAlTb alloy of the power generation body 10 may contain 30 at % or less of impurities other than Fe, Al, and Tb as long as the composition of Fe, Al, and Tb falls within the above-described range.

The power generation body 10 includes a thermoelectric conversion function derived from the FeAlTb alloy. It is desirable that the FeAlTb alloy of the power generation body 10 is 100% with Fe, Al, and Tb. However, a substance other than Fe, Al, and Tb may actually be mixed as impurities in the FeAlTb alloy of the power generation body 10, depending on a manufacturing step and a storage method. For example, impurities such as oxygen, carbon, and copper may be mixed in the FeAlTb alloy. Further, other elements used in a device that manufactures the FeAlTb alloy may also be mixed as impurities in the FeAlTb alloy. Note that some sort of mixture may be intentionally added to the FeAlTb alloy in order to improve a function such as corrosion resistance. As long as the FeAlTb alloy contains 70 at % or more of the three elements of Fe, Al, and Tb, the thermoelectric conversion function of the power generation body 10 is not considerably lost.

As described above, the thermoelectric conversion element according to the present example embodiment includes the power generation body including the iron-aluminum-terbium based magnetic alloy material containing a total of 70 atomic percent or more of the three elements of iron, aluminum, and terbium. When the temperature gradient is applied, the power generation body generates the electromotive force in the direction substantially perpendicular to each of the direction of the magnetization of the magnetic alloy material and the direction of the applied temperature gradient due to the anomalous Nernst effect that appears in the magnetic alloy material.

As described above, the magnetic alloy material according to the present example embodiment is the iron-aluminum-terbium based magnetic alloy material containing a total of 70 atomic percent or more of the three elements of iron, aluminum, and terbium.

In the magnetic alloy material according to one aspect of the present example embodiment, a composition ratio of aluminum is equal to or more than 20 atomic percent and equal to or less than 35 atomic percent in the three elements of iron, aluminum, and terbium. In the magnetic alloy material according to one aspect of the present example embodiment, a composition ratio of Tb is equal to or more than 5 atomic percent and equal to or less than 20 atomic percent. In the magnetic alloy material according to one aspect of the present example embodiment, a composition ratio of iron, aluminum, and terbium is 6:2:1 in the three elements of iron, aluminum, and terbium.

The FeAlTb alloy included in the power generation body of the thermoelectric conversion element according to the present example embodiment acquires the electromotive force about few times greater than that of an FePt alloy and a CoPt alloy and about a dozen % times greater than that of an FeAl alloy. In other words, the present example embodiment is able to provide the magnetic alloy material having the anomalous Nernst effect greater than that of a general magnetic alloy material, and having great thermoelectric conversion efficiency.

Further, the thermoelectric conversion element according to one aspect of the present example embodiment includes the power generation body including the iron-aluminum-terbium based magnetic alloy material containing a total of 70 atomic percent or more of the three elements of iron, aluminum, and terbium. The power generation body has a plate-like shape including two main surfaces facing each other, and the magnetic alloy material is magnetized in the in-plane direction of the main surface. When the temperature gradient is applied to the out-of-plane direction of the main surface, the electromotive force is generated in the power generation body in the direction substantially perpendicular to each of the direction of the magnetization of the magnetic alloy material and the direction of the applied temperature gradient.

### Second Example Embodiment

Next, a thermoelectric conversion element according to a second example embodiment will be described with reference to a drawing. The thermoelectric conversion element according to the present example embodiment includes a power generation body having a structure in which a conductive magnetic layer (also referred to as a first magnetic layer) in which an anomalous Nernst effect appears and an insulating magnetic layer (also referred to as a second magnetic layer) in which a spin Seebeck effect appears are laminated. The first magnetic layer includes the FeAlTb alloy according to the first example embodiment.

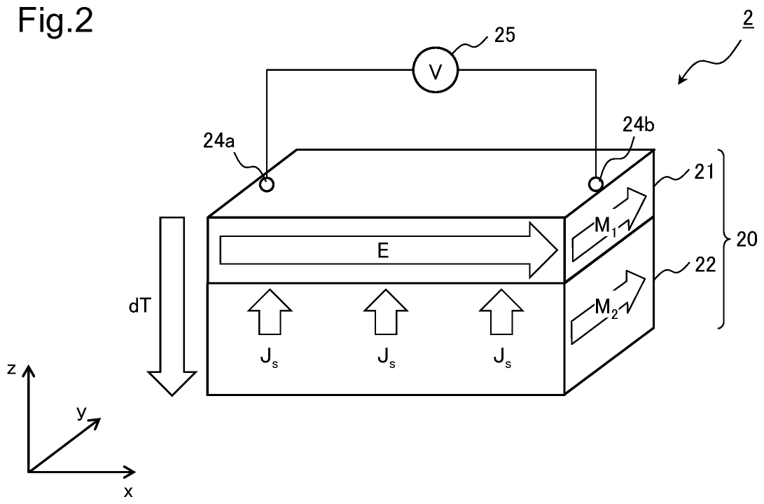

FIG. 2 is a schematic diagram illustrating one example of a thermoelectric conversion element 2 according to the present example embodiment. The thermoelectric conversion element 2 includes a power generation body 20 having a structure in which a first magnetic layer 21 and a second magnetic layer 22 are laminated. FIG. 2 illustrates an example in which an electrode terminal 24a and an electrode terminal 24b are installed on a main surface of the first magnetic layer 21, and a voltmeter 25 is installed between the electrode terminal 24a and the electrode terminal 24b. Note that the voltmeter 25 is not included in the configuration of the thermoelectric conversion element 2 according to the present example embodiment. Hereinafter, a direction parallel to the main surface of the power generation body 20 is referred to as an in-plane direction, and a direction perpendicular to the main surface of the power generation body 20 is referred to as an out-of-plane direction.

The first magnetic layer 21 is a layer of a magnetic material having a great anomalous Nernst effect. The first magnetic layer 21 includes magnetization M₁ in one direction (y direction in FIG. 2). The FeAlTb alloy according to the first example embodiment is applied to the first magnetic layer 21.

For example, the first magnetic layer 21 can be formed by using a sputtering method, a plating method, a vacuum vapor deposition method, or the like.

The first magnetic layer 21 includes two functions. A first function is a function of spin current-current conversion that converts a spin current flowing in by the spin Seebeck effect of the second magnetic layer 22 into an electromotive force (electric field E_{SSE}) by an inverse spin Hall effect (SSE: spin Seebeck effect). A second function is a function of directly generating an electromotive force (electric field E_{ANE}) from a temperature gradient dT by the anomalous Nernst effect (ANE: anomalous Nernst effect).

A direction of the electric field E_{ANE} generated by the anomalous Nernst effect is determined by an outer product of the magnetization M₁ of the first magnetic layer 21 and the temperature gradient dT as indicated by Expression 1 below.

E_{ANE}∝M₁×dT (1)

Note that, in Expression 1, “∝” indicates that the direction of the electric field E_{ANE} generated by the anomalous Nernst effect is determined by the outer product of the magnetization M₁ of the first magnetic layer 21 and the temperature gradient dT.

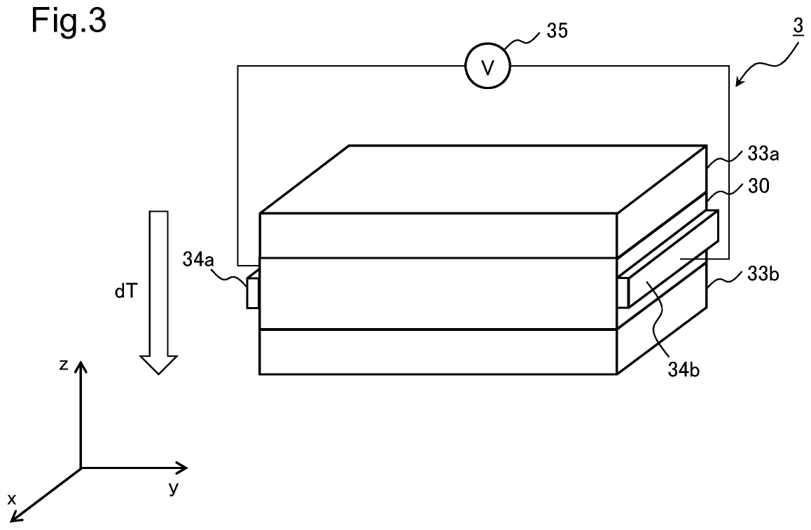

The second magnetic layer 22 is a layer of a magnetic material in which the spin Seebeck effect appears. Similarly to the first magnetic layer 21, the second magnetic layer 22 includes magnetization M₂ in one direction (y direction in FIG. 3). The second magnetic layer 22 includes a magnetic material such as yttrium iron garnet (YIG), YIG (Bi:YIG) to which Bi is added, and nickel zinc ferrite (NiZn ferrite). Examples of the yttrium iron garnet includes Y₃Fe₅O₁₂ and BiY₂Fe₅O₁₂ to which Bi is added, as one example. Examples of the NiZn ferrite include (Ni, Zn)ₓFe₃₋ₓO₄ as one example (x is a positive number of 1 or less).

When the thermoelectric conversion element 2 is film-formed on some sort of base substrate, the second magnetic layer 22 can be film-formed by using, for example, a sputtering method, an organic metal decomposition method, a pulsed laser sedimentation method, a sol-gel method, an aerosol deposition method, a ferrite plating method, a liquid phase epitaxy method, or the like.

In the second magnetic layer 22, when the temperature gradient dT in the out-of-plane direction (z direction in FIG. 2) is applied to the main surface, a spin current Jₛ is generated by the spin Seebeck effect. A direction of the spin current Jₛ is a direction (z direction in FIG. 2) parallel or antiparallel to the direction (z direction in FIG. 2) of the temperature gradient dT. In the example in FIG. 2, when the temperature gradient dT in the −z direction is applied to the second magnetic layer 22, the spin current Jₛ along the +z direction or the −z direction is generated. When the spin current Jₛ is generated at an interface between the first magnetic layer 21 and the second magnetic layer 22, an electromotive force in the in-plane direction is generated in the first magnetic layer 21 by the inverse spin Hall effect.

It is desirable that the second magnetic layer 22 has small thermal conductivity in terms of thermoelectric conversion efficiency. Thus, it is desirable that a magnetic insulator without having conductivity and a magnetic semiconductor having relatively great electrical resistance are used for the second magnetic layer 22.

A direction of the electric field E_{SSE} generated by the spin Seebeck effect is determined by an outer product of the magnetization M₂ of the second magnetic layer 22 and the temperature gradient dT as indicated by Expression 2 below.

E_{SSE}∝M₂×dT (2)

Note that, in Expression 2, “∝” indicates that the direction of the electric field E_{SSE} generated by the spin Seebeck effect is determined by the outer product of the magnetization M₂ of the second magnetic layer 22 and the temperature gradient dT.

A sign of an actual electric field is also dependent on a material. However, in a case of the configuration of the thermoelectric conversion element 2 illustrated in FIG. 2, when the directions of the magnetization M₁ and the magnetization M₂ are the same, both of the electric field E_{SSE} and the electric field E_{ANE} are generated in the same direction with respect to a certain temperature gradient dT. Therefore, under such a condition, the anomalous Nernst effect and the spin Seebeck effect enhance each other, and an absolute value of the generated electric field is a value (E_{Hybrid}) to which an electromotive force by the two effects is added as indicated in Equation (3) below.

|E_{Hybrid}|=|E_{SSE}|+|E_{ANE}| (3)

Note that Equation 3 is applied to when the electric field E_{SSE} and the electric field E_{ANE} are generated in the same direction.

In the example in FIG. 2, a direction of the magnetization M₁ of the first magnetic layer 21 and the magnetization M₂ of the second magnetic layer 22 is the +y direction, and thus an electromotive force in the +x direction is generated in the first magnetic layer 21 when the direction of the temperature gradient dT is the −z direction.

In order to effectively perform thermoelectric conversion in the power generation body 20, the temperature gradient dT needs to be maintained. In order to maintain the temperature gradient dT, it is desirable that a thickness of the second magnetic layer 22 is equal to or more than 1 micrometer (μm). Further, in order to effectively make the spin Seebeck effect appear, an influence of dissipation of a spin current within a film needs to be avoided. In order to avoid an influence of dissipation of a spin current within a film, it is desirable that a film thickness of the first magnetic layer 21 is equal to or less than 100 nanometers (nm). Further, in order to support the thermoelectric conversion element 2, a substrate may be provided below the second magnetic layer 22.

As described above, the thermoelectric conversion element according to the present example embodiment includes the power generation body having the structure in which the first magnetic layer including the magnetic alloy material according to the first example embodiment and the second magnetic layer in which the spin Seebeck effect appears by application of the temperature gradient are laminated. In other words, the thermoelectric conversion element according to the present example embodiment includes the power generation body having the structure in which the first magnetic layer including the magnetic alloy material and the second magnetic layer in which the spin Seebeck effect appears by application of the temperature gradient are laminated. For example, it is suitable that a thickness of the first magnetic layer is equal to or less than 100 nanometers.

In the thermoelectric conversion element according to the present example embodiment, the anomalous Nernst effect and the spin Seebeck effect can both be used by the structure in which the first magnetic layer including the magnetic alloy material and the second magnetic layer in which the spin Seebeck effect appears by application of the temperature gradient are laminated. Thus, the thermoelectric conversion element according to the present example embodiment can generate a thermoelectromotive force greater than that of the thermoelectric conversion element according to the first example embodiment.

### Third Example Embodiment

Next, a thermoelectric conversion element according to a third example embodiment will be described with reference to drawings. The thermoelectric conversion element according to the present example embodiment includes a power generation body having a structure in which a conductive magnetic network in which the anomalous Nernst effect appears and an insulating magnetic particle in which the spin Seebeck effect appears are composite. The magnetic network includes the FeAlTb alloy according to the first example embodiment.

FIG. 3 is a schematic diagram illustrating one example of a thermoelectric conversion element 3 according to the present example embodiment. The thermoelectric conversion element 3 has a structure in which a power generation body 30 is sandwiched between a first support layer 33a and a second support layer 33b. FIG. 3 illustrates an example in which an electrode terminal 34a and an electrode terminal 34b are installed on two side end surfaces of the power generation body 30 facing each other, and a voltmeter 35 is installed between the electrode terminal 34a and the electrode terminal 34b. Note that the voltmeter 35 is not included in the configuration of the thermoelectric conversion element 3 according to the present example embodiment. Hereinafter, a direction parallel to a main surface of the power generation body 30 is referred to as an in-plane direction, and a direction perpendicular to the main surface of the power generation body 30 is referred to as an out-of-plane direction.

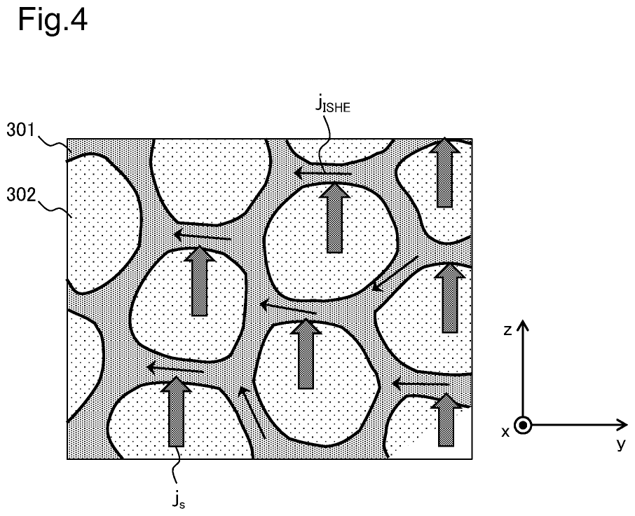

FIG. 4 is a schematic diagram illustrating one example of a configuration of the power generation body 30. FIG. 4 is a diagram in which a section of the power generation body 30 cut in a plane parallel to an zy plane is viewed from a viewpoint of the +x direction. The power generation body 30 includes a magnetic network 301, and a granular magnetic particle 302 dispersed inside the magnetic network 301. In other words, in the power generation body 30, the granular magnetic particles 302 are disposed away from each other, and the magnetic network 301 spreads like a net in such a way as to fill a gap between a particle and a particle of the magnetic particles 302.

The magnetic network 301 includes a magnetic material having a great anomalous Nernst effect. The FeAlTb alloy according to the first example embodiment is applied to the magnetic network 301.

The magnetic network 301 includes a three-dimensional network structure inside the power generation body 30, and thus the electrode terminal 34a and the electrode terminal 34b are electrically connected to each other.

The magnetic particle 302 includes a magnetic material in which the spin Seebeck effect appears. The magnetic particle 302 includes a magnetic material such as yttrium iron garnet (YIG) and nickel zinc ferrite (NiZn ferrite). Examples of the yttrium iron garnet includes Y₃Fe₅O₁₂ as one example. Examples of the NiZn ferrite include (Ni, Zn, Fe)₃O₄ as one example.

The magnetic particle 302 includes magnetization in the in-plane direction (x direction in FIG. 4). Note that, in order to maximize power generation efficiency, it is desirable that a grain size of the individual magnetic particle 302 is about a transition length of a spin current (magnon current) induced by the spin Seebeck effect. Specifically, it is desirable that an average grain size of the magnetic particles 302 is equal to or more than 300 nm and equal to or less than 10 μm.

The first support layer 33a and the second support layer 33b are disposed on both of the main surfaces of the power generation body 30. The first support layer 33a is disposed on an upper surface (also referred to as a first surface) of the power generation body 30. The second support layer 33b is disposed on a lower surface (also referred to as a second surface) of the power generation body 30. In the thermoelectric conversion element 3, the power generation body 30 is supported by the first support layer 33a and the second support layer 33b, and thus strength of the whole element is enhanced.

It is desirable that an insulating material that does not pass electricity or a semiconductor material having resistivity equal to or more than 1 ohm meter (Ωm) is used for the first support layer 33a and the second support layer 33b in order to extract an electromotive force generated in the power generation body 30 to an outside without a loss.

It is desirable that a material constituting the first support layer 33a and the second support layer 33b has a melting point lower than that of a metal material and a magnetic insulating material constituting the power generation body 30 for the sake of manufacturing of the thermoelectric conversion element 3. The magnetic particle 302 in which the spin Seebeck effect appears is used in a temperature range equal to or less than the Curie temperature of a magnetic body included in the magnetic particle 302. Thus, it is preferable that a melting point of a material for the first support layer 33a and the second support layer 33b is higher than the Curie temperature of the magnetic particle 302 in such a way that the material for the first support layer 33a and the second support layer 33b does not melt in the temperature range equal to or less than the Curie temperature of the magnetic body included in the magnetic particle 302.

In other words, when the thermoelectric conversion element 3 is manufactured, a sintering temperature of the thermoelectric conversion element 3 is set between a minimum sintering temperature of the first support layer 33a and the second support layer 33b and a minimum sintering temperature of the power generation body 30. In this way, the thermoelectric conversion element 3 can be integrally solidified at high strength by heat treatment at a temperature lower than an original sintering temperature of the power generation body 30 by using a material having a low melting point (and sintering temperature) for the first support layer 33a and the second support layer 33b.

For example, it is assumed that a ferrite based material having the Curie temperature of 300 to 400° C. and a melting point of 1200 to 1700° C. is used as the magnetic particle 302. In this case, it is desirable that a melting point of a material constituting the first support layer 33a and the second support layer 33b is equal to or more than 400° C. and equal to or less than 1200° C. Specifically, a bismuth oxide Bi₂O₃, a molybdenum oxide MoO₃, a germanium oxide GeO₂, and the like are suitable for a material constituting the first support layer 33a and the second support layer 33b.

The electrode terminal 34a and the electrode terminal 34b are installed on the two side end surfaces of the power generation body 30 facing each other. In FIG. 3, the electrode terminal 34a is installed on a side end surface (also referred to as a third surface) on the −y side, and the electrode terminal 34b is installed on a side end surface (also referred to as a fourth surface) on the +y side. The electrode terminal 34a and the electrode terminal 34b are terminals for extracting a thermoelectromotive force generated in the y direction by a temperature gradient dT applied in the −z direction. The electrode terminal 34a and the electrode terminal 34b are formed of a material having conductivity.

When the temperature gradient dT in the out-of-plane direction (z direction in FIG. 3) is applied to the thermoelectric conversion element 3, the spin Seebeck effect appears in the magnetic particle 302. When the spin Seebeck effect appears in the magnetic particle 302, a spin current jₛ is generated at an interface between the magnetic network 301 and the magnetic particle 302 as in FIG. 4. When the spin current jₛ is generated at the interface between the magnetic network 301 and the magnetic particle 302, an electromotive force in the in-plane direction is generated in the magnetic network 301 by an inverse spin Hall effect. FIG. 4 schematically illustrates a situation where a current j_{ISHE} flows in the magnetic network 301 by the inverse spin Hall effect (ISHE: inverse spin Hall effect). Since the magnetic network 301 spreads like a network and is dispersed in the power generation body 30, an electromotive force generated in each portion of a composite body is added as a whole, and an electromotive force in the in-plane direction (y direction in FIG. 3) is acquired via the electrode terminal 34a and the electrode terminal 34b.

As described above, the thermoelectric conversion element according to the present example embodiment includes the power generation body formed of the magnetic network including the magnetic alloy material according to the first example embodiment, and the magnetic particle dispersed inside the magnetic network. The magnetic particle makes the spin Seebeck effect appear by application of the temperature gradient. In other words, the thermoelectric conversion element according to the present example embodiment has a structure in which the magnetic particle in which the spin Seebeck effect appears is dispersed and maintained in the magnetic network in which the anomalous Nernst effect appears.

In the structure of the thermoelectric conversion element according to the second example embodiment, due to a spin current in the second magnetic layer being relieved, even when the power generation body is made thick, power generation efficiency does not efficiently increase. In contrast, in the thermoelectric conversion element according to the present example embodiment, power generation efficiency efficiently increases by making the power generation body thick with the composite structure formed of the magnetic network in which the anomalous Nernst effect appears and the magnetic particle in which the spin Seebeck effect appears.

### Fourth Example Embodiment

Next, a thermoelectric conversion module according to a fourth example embodiment will be described with reference to drawings. The thermoelectric conversion module according to the present example embodiment includes a power generation body having a pipe structure formed of a conductive magnetic body in which an anomalous Nernst effect appears.

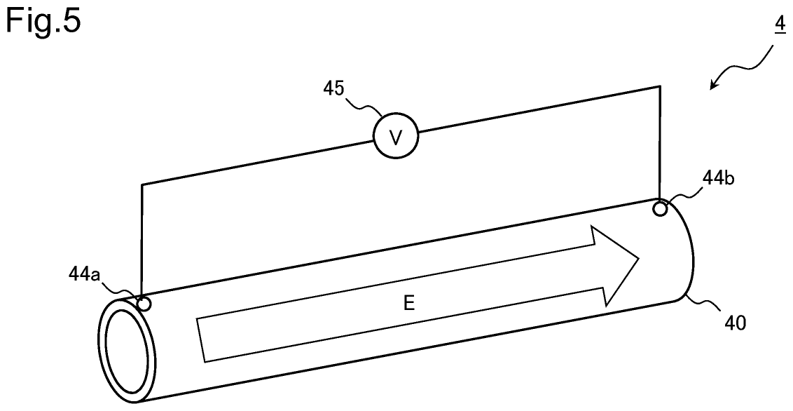

FIG. 5 is a schematic diagram illustrating one example of a thermoelectric conversion module 4 according to the present example embodiment. The thermoelectric conversion module 4 includes a power generation body 40 having a pipe structure. FIG. 5 illustrates an example in which an electrode terminal 44a and an electrode terminal 44b are installed on an outer surface of the power generation body 40, and a voltmeter 45 is installed between the electrode terminal 44a and the electrode terminal 44b. Note that the voltmeter 45 is not included in the configuration of the thermoelectric conversion module 4 according to the present example embodiment. Hereinafter, a direction parallel to a pipe axial direction of the power generation body 40 having the pipe structure is referred to as an in-plane direction, and a direction perpendicular to the pipe axial direction of the power generation body 40 having the pipe structure is referred to as an out-of-plane direction.

In the present example embodiment, an example of flowing a heating medium into the power generation body 40 having the pipe structure is indicated. The outside of the power generation body 40 having the pipe structure is thermally connected to a heating medium having a temperature different from that of the heating medium flowing inside the power generation body 40 having the pipe structure.

The power generation body 40 has a structure in which any of the power generation bodies 10 to 30 according to the first to third example embodiments is formed in a pipe shape. The power generation body 40 includes the FeAlTb alloy according to the first example embodiment as a thermoelectric conversion material.

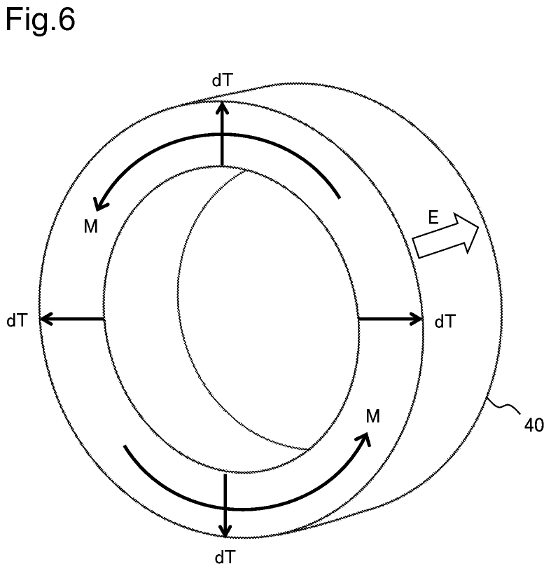

FIG. 6 is a schematic diagram illustrating a relationship among the power generation body 40 having the pipe structure, a temperature gradient dT, a magnetization direction M, and an electromotive force direction E. Any one of the heating medium flowing inside the power generation body 40 having the pipe structure and the heating medium thermally connected to the outside of the power generation body 40 having the pipe structure is used as a hot heat source or a cold heat source, and the other is used as a heat bath. The temperature gradient dT is generated in a thickness direction of the thermoelectric conversion material constituting the power generation body 40 having the pipe structure, and an amount and a direction thereof are dependent on a state of temperature inside and outside the pipe.

As in FIG. 6, magnetization of the thermoelectric conversion material constituting the power generation body 40 having the pipe structure is defined along a circumferential direction of the pipe while being orthogonal to the temperature gradient dT. As a method of defining magnetization, a method using magnetic shape anisotropy and magnetocrystalline anisotropy, or a general technique being industrially used, such as a magnetization technique using a magnetic field created by a direct current, can be used.

As in FIG. 6, when the power generation body 40 having the pipe structure is magnetized along the circumferential direction of the pipe, the electromotive force E is generated in the in-plane direction perpendicular to a direction of each of the temperature gradient dT and the magnetization M by the anomalous Nernst effect. Thermoelectric conversion can be achieved by extracting the electromotive force E in the in-plane direction perpendicular to the direction of each of the magnetization M and the temperature gradient dT from between the electrode terminal 44a and the electrode terminal 44b.

As described above, the thermoelectric conversion module according to the present example embodiment includes the power generation body having the pipe structure including the magnetic alloy material according to the first example embodiment. In the thermoelectric conversion module according to one aspect of the present example embodiment, the power generation body having the pipe structure is magnetized in the circumferential direction centered on the pipe axis. Further, the thermoelectric conversion module according to one aspect of the present example embodiment includes at least the two electrode terminals disposed at an interval along the pipe axial direction on the outer surface of the power generation body having the pipe structure.

The thermoelectric conversion module according to the present example embodiment is magnetized in the circumferential direction of the power generation body having the pipe structure. Thus, the electromotive force along the pipe axial direction of the power generation body having the pipe structure is generated by the temperature gradient due to a temperature difference between the heating medium flowing inside the pipe and the heating medium outside the pipe. The electromotive force generated in the thermoelectric conversion module according to the present example embodiment can be extracted by installing the two terminals on the outer surface of the pipe. The thermoelectric conversion module according to the present example embodiment can increase a voltage as an interval between the two terminals installed on the outer surface of the pipe increases.

An electromotive force by a Seebeck effect at magnitude equal to or more than an anomalous Nernst electromotive force may be actually generated due to a temperature difference along the pipe axial direction of the power generation body having the pipe structure. When the thermoelectric conversion module according to the present example embodiment is used as a power source, it is preferable that a thermoelectromotive force by the Seebeck effect and a thermoelectromotive force by the anomalous Nernst effect are used as one thermoelectromotive force without distinction. Thus, it is preferable that a magnetization direction of the thermoelectric conversion module is appropriately set together with a sign of a Seebeck electromotive force determined according to a temperature difference of a heat source and a heat bath to be tried out and a direction of a fluid flowing inside the pipe. When the magnetization direction of the thermoelectric conversion module can be appropriately set, the Seebeck electromotive force and the anomalous Nernst electromotive force can be added together without canceling each other out.

When the thermoelectric conversion module according to the present example embodiment is applied to a piping component, the electromotive force can be generated in the pipe axial direction by applying the temperature gradient between the inside and the outside the pipe. For example, the thermoelectric conversion module according to the present example embodiment can be applied to a piping component in which a fluid flows, such as a water pipe and a drain pipe. Further, for example, the thermoelectric conversion module according to the present example embodiment can also be applied to a mechanism such as a heat pipe. Note that the thermoelectric conversion module according to the present example embodiment is not limited to the application example described above as long as a temperature difference between the inside and the outside of the pipe can be used, and the thermoelectric conversion module can be applied for any use. For example, in a case in which an electric wire is stored inside the thermoelectric conversion module according to the present example embodiment, an electromotive force can also be generated in the pipe axial direction by using a heat flow, which flows toward the outside of the pipe, due to Joule heat generated by a current flowing through the electric wire.

### First Example

Next, Example 1 related to the thermoelectric conversion element 1 according to the first example embodiment will be described with reference to drawings. The thermoelectric conversion element according to the present example includes an FeAlTb alloy as a power generation body. Note that the FeAlTb alloy used for the power generation body of the thermoelectric conversion element according to the present example may include mainly oxygen as impurities for the sake of manufacturing. A proportion of oxygen and the like included as impurities is, for example, about 5 to 15 percent (%).

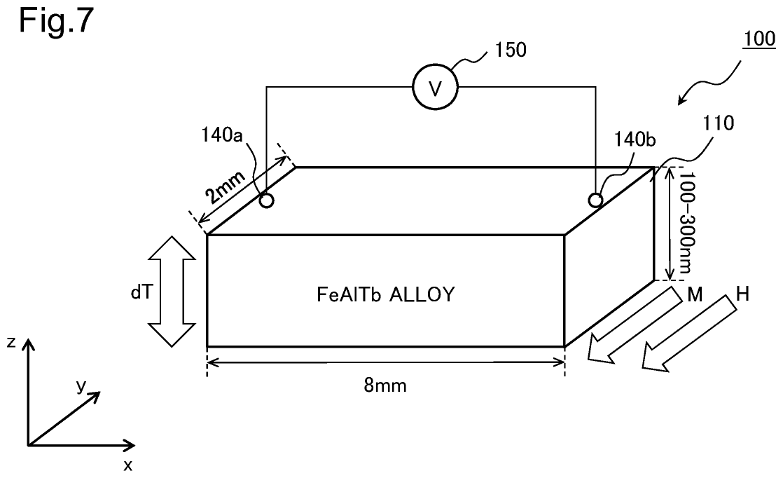

FIG. 7 is a schematic diagram illustrating one example of a thermoelectric conversion element 100 according to the present example. The thermoelectric conversion element 100 includes a power generation body 110 including the FeAlTb alloy. The power generation body 110 was formed with a length in the x direction of 8 millimeters (mm), a length in the y direction of 2 mm, and a thickness in the z direction of 100 to 300 nanometers (nm).

In the present example, Fe, Al, and Tb were deposited at about 100 to 300 nm on a substrate by a simultaneous sputtering method.

In the present example, in order to examine dependence of the anomalous Nernst effect of the FeAlTb alloy on a composition, a plurality of thermoelectric conversion elements 100 varying in a content ratio of each of Fe, Al, and Tb were manufactured, and a thermoelectromotive force V of each of the thermoelectric conversion elements 100 was measured. As in FIG. 7, in order to measure the thermoelectromotive force V of the thermoelectric conversion element 100, an electrode terminal 140a and an electrode terminal 140b were installed on one of main surfaces of the power generation body 110, and a voltmeter 150 was installed between the electrode terminal 140a and the electrode terminal 140b. An interval between the electrode terminal 140a and the electrode terminal 140b was set to approximately 8 mm.

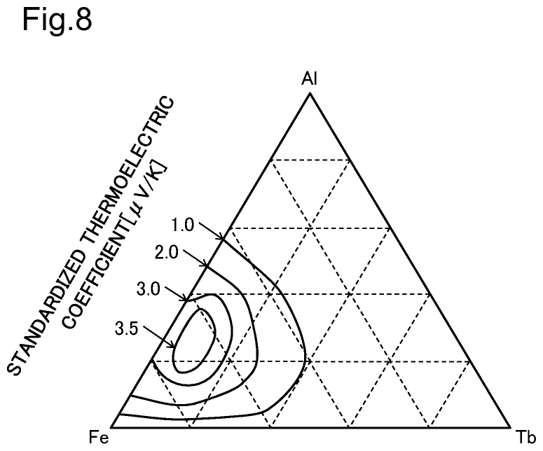

FIG. 8 is a graph illustrating dependence (atomic ratio), on an Fe-Al-Tb composition, of a standardized thermoelectric coefficient, which was calculated from the thermoelectromotive force V of the plurality of thermoelectric conversion elements 100. FIG. 8 illustrates a balance of a composition ratio in a three element system of Fe, Al, and Tb except for impurities. The standardized thermoelectric coefficient is a value indicating thermoelectric performance unique to a material standardized by a length Lz in the z direction and a length Lx in the x direction in a state where there is a temperature gradient dT in the z direction and the thermoelectromotive force V in the x direction is generated. The standardized thermoelectric coefficient is calculated by Equation 4 below.

(Standardized thermoelectric coefficient)=V/dT×(Lz/Lx) (4)

A unit of the standardized thermoelectric coefficient calculated in the present example is a microvolt per kelvin (μV/K).

FIG. 8 illustrates, by a solid line, composition ratios in which the standardized thermoelectric coefficient is 1.0, 2.0, 3.0, and 3.5. As in FIG. 8, the standardized thermoelectric coefficient was greater than that of an Fe-Al binary alloy and greater than that of an Fe-Tb binary alloy in a composition range in which a composition ratio of Al is 20 to 35 at % and a composition ratio of Tb is 5 to 20 at %. In other words, the FeAlTb alloy in which the composition ratio of Al is 20 to 35 at %, the composition ratio of Tb is 5 to 20 at %, and the rest is Fe had thermoelectric conversion efficiency greater than an FeAl alloy and an FeTb alloy.

As described above, according to the present example, it could be confirmed that the FeAlTb alloy in which the composition ratio of Al is 20 to 35 at %, the composition ratio of Tb is 5 to 20 at %, and the rest is Fe had thermoelectric conversion efficiency greater than the FeAl alloy and the FeTb alloy.

### Second Example

Next, Example 2 related to the thermoelectric conversion element 1 according to the first example embodiment will be described with reference to drawings. The power generation body was formed in a thin film by the sputtering method in Example 1, but the present example indicates an example in which a power generation body was formed as a sintering body. A thermoelectric conversion element according to the present example includes an Fe₆Al₂Tb₁ alloy as a power generation body. Note that the Fe₆Al₂Tb₁ alloy used for the power generation body of the thermoelectric conversion element according to the present example may include mainly carbon and oxygen as impurities for the sake of manufacturing.

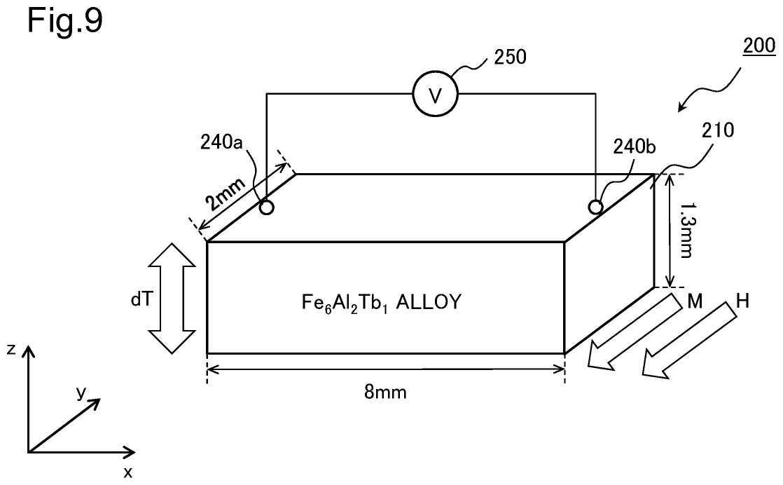

FIG. 9 is a schematic diagram illustrating one example of a thermoelectric conversion element 200 according to the present example. The thermoelectric conversion element 200 includes a power generation body 210 including the Fe₆Al₂Tb₁ alloy. The power generation body 210 was formed with a length in the x direction of 8 mm, a length in the y direction of 2 mm, and a thickness in the z direction of 1.3 mm.

In the present example, the power generation body 210 was manufactured by a powder metallurgy method using a discharge plasma sintering device. First, Fe powder having an average grain size of 4 μm, Al powder having an average grain size of 3 μm, and Tb rough powder having an average grain size of about 800 μm were compounded in an atomic composition ratio of 6:2:1, and were mixed in a mortar for 40 minutes in such a way as to be uniformly mixed, and thus mixed powder was adjusted. Next, the adjusted mixed powder filled in a graphite die and was sintered for 1 hour 30 minutes at 950° C. in a vacuum in a state where pressure of 50 mega pascal (Mpa) was applied, and thus the Fe₆Al₂Tb₁ alloy was manufactured.

FIG. 9 illustrates that an electrode terminal 240a and an electrode terminal 240b are installed on one of main surfaces of the power generation body 210, and illustrates a voltmeter 250 that measures a voltage between the electrode terminal 240a and the electrode terminal 240b.

At a time of a measurement of an electromotive force by thermoelectric conversion, a copper block having a width of 5 mm was pressed against a central portion of both of the main surfaces of the thermoelectric conversion element 200 from the top and bottom, and one of the main surfaces was heated and the other main surface was cooled, thereby applying a temperature gradient dT. Therefore, although a distance between the electrode terminals was approximately 8 mm, an area of a region in which a thermoelectromotive force was generated by actual application of a temperature difference was a product (10 square millimeter mm²) of a width (5 mm) of the copper block and a width (2 mm) of the thermoelectric conversion element 200.

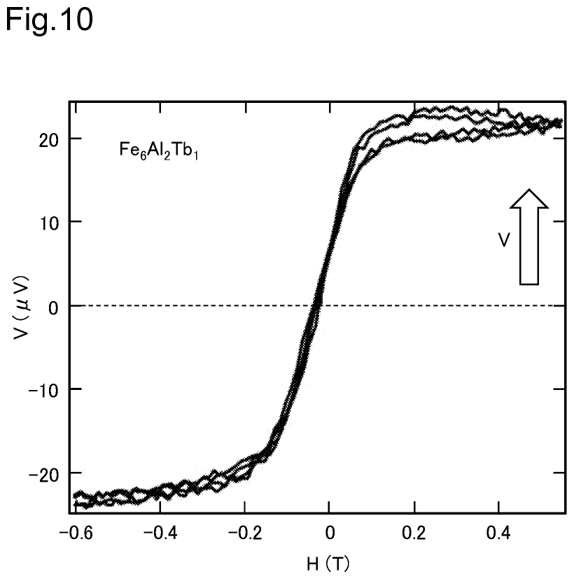

FIG. 10 is a graph illustrating dependence, on an external magnetic field H, of an output voltage V generated when the temperature gradient dT of 2.8 kelvin (K) is applied between both of the main surfaces of the thermoelectric conversion element 200. In the thermoelectric conversion element 200, a thermoelectromotive force was generated in a direction perpendicular to a direction of each of the temperature gradient dT and the external magnetic field H (magnetization M), and the output voltage V was generated between the electrode terminal 240a and the electrode terminal 240b.

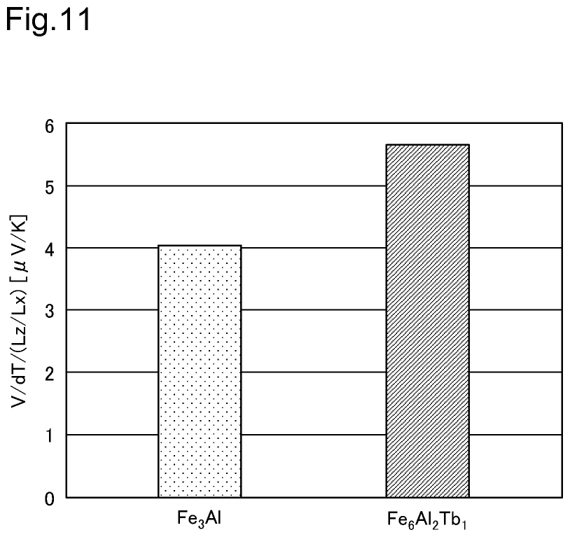

FIG. 11 is a graph in which a standardized thermoelectric coefficient V/dT (Lz/Lx) of the thermoelectric conversion element 200 including the Fe₆Al₂Tb₁ alloy according to the present example is compared with a standardized thermoelectric coefficient V/dT (Lz/Lx) of a thermoelectric conversion element including an Fe₃Al alloy without including Tb. As in FIG. 11, the thermoelectric conversion element 200 including the Fe₆Al₂Tb₁ alloy according to the present example had a standardized thermoelectric coefficient greater than that of the thermoelectric conversion element including the Fe₃Al alloy without including Tb.

As described above, according to the present example, it could be confirmed that the thermoelectric conversion element including the Fe₆Al₂Tb₁ alloy had thermoelectric conversion efficiency greater than that of the thermoelectric conversion element including the Fe₃Al alloy without including Tb.

In general, there is a possibility that a thin film system having a thickness of about several tens to several hundreds of nanometers and a bulk system having a thickness of equal to or more than 10 μm may vary in thermoelectric performance. According to Examples 1 to 2, it could be confirmed that an effect of improving the thermoelectric performance by adding Tb to the Fe-Al alloy system was acquired in both of the thin film system and the bulk system.

### Third Example

Next, Example 3 related to the thermoelectric conversion module 4 according to the fourth example embodiment will be described with reference to a drawing. In the present example, an example of manufacturing a thermoelectric conversion module including, as a power generation body, an Fe₆Al₂Tb₁ alloy formed in a pipe shape is indicated. Note that the Fe₆Al₂Tb₁ alloy used for the power generation body of the thermoelectric conversion module according to the present example may include mainly carbon and oxygen as impurities for the sake of manufacturing.

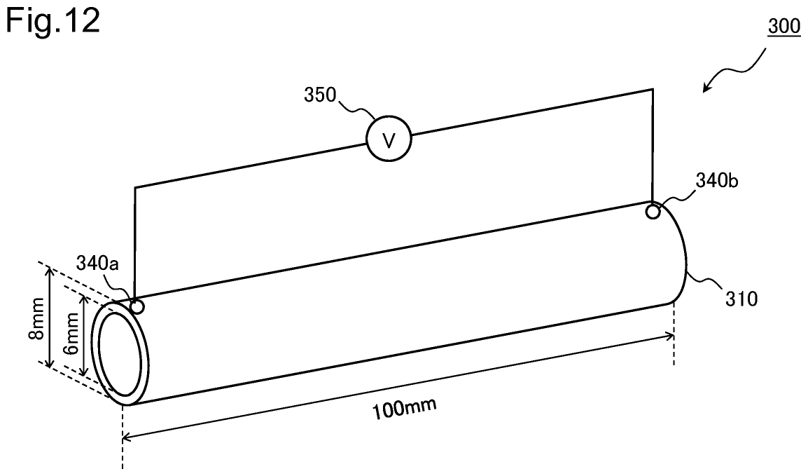

FIG. 12 is a schematic diagram illustrating one example of a thermoelectric conversion module 300 according to the present example. The thermoelectric conversion module 300 includes a power generation body 310 including the Fe₆Al₂Tb₁ alloy having a pipe structure.

According to the present example, first, a round bar member was manufactured by using a rolling technique from a melting body of a bulk of the Fe₆Al₂Tb₁ alloy, and then the power generation body 310 having a hollow pipe structure was manufactured by using rolling in the same way. A shape of the power generation body 310 is a pipe shape having an outer diameter of 8 mm, an inner diameter of 6 mm, a thickness of 1 mm, and a length of 100 mm.

Subsequently, magnetization was performed in order to use the power generation body 310 as the thermoelectric conversion module 300. The magnetization was performed by disposing magnetization copper wiring in such a way as to penetrate an inside of the power generation body 310 having the hollow pipe structure, and flowing a direct-current pulsed current. Subsequently, a polymer film was vapor-deposited by exposing the power generation body 310 to parylene steam in a vacuum, and an insulating coating film was formed on inner and outer walls of the power generation body 310 having the hollow pipe structure. The polymer film was formed on the entire surface of the power generation body 310 having the hollow pipe structure, and a thickness of the polymer film was approximately 1 μm. Then, a part of the polymer film at both ends of an outer surface of the power generation body 310 having the hollow pipe structure was removed, and an electrode terminal 340a and an electrode terminal 340b were formed on places acquired by removing the polymer film. It was confirmed that the Fe₆Al₂Tb₁ alloy and the electrode terminals (the electrode terminal 340a and the electrode terminal 340b) were electrically connected in the electrode terminal 340a and the electrode terminal 340b. It was assumed that the thermoelectric conversion module 300 manufactured in the steps above had a thermoelectric conversion coefficient of 5 mV/K and a thermal conductivity 15 W/mK.

Subsequently, an electromotive force of the thermoelectric conversion module 300 was measured. First, the outside of the thermoelectric conversion module 300 was put in a sufficient amount of a cooling water bath at 25° C. Then, hot water at approximately 100° C. was introduced at a flow rate of 5 liters per minute (5 L/min) into the inside of the thermoelectric conversion module 300. At this time, in the thermoelectric conversion module 300 having a thickness of 1 mm, a temperature difference of approximately 4 kelvins (K) occurred, and a thermoelectromotive force of approximately 20 millivolts (mV) by the anomalous Nernst effect was generated. Further, extracted electric power of approximately 10 milliwatts (mW) at maximum could be acquired outside the thermoelectric conversion module 300.

As described above, according to the present example, it could be confirmed that power could be generated by a temperature gradient between a heating medium flowing in the power generation body having the pipe structure and a heating medium outside in the thermoelectric conversion module including the Fe₆Al₂Tb₁ alloy formed in the pipe shape as the power generation body.

The previous description of embodiments is provided to enable a person skilled in the art to make and use the present invention. Moreover, various modifications to these example embodiments will be readily apparent to those skilled in the art, and the generic principles and specific examples defined herein may be applied to other embodiments without the use of inventive faculty. Therefore, the present invention is not intended to be limited to the example embodiments described herein but is to be accorded the widest scope as defined by the limitations of the claims and equivalents.

Further, it is noted that the inventor's intent is to retain all equivalents of the claimed invention even if the claims are amended during prosecution.

What is claimed is:

1. An iron-aluminum-terbium based magnetic alloy material, comprising
a total of 70 atomic percent or more of three elements of iron, aluminum, and terbium.

2. The magnetic alloy material according to claim 1, wherein
a composition ratio of aluminum is equal to or more than 20 atomic percent and equal to or less than 35 atomic percent in three elements of iron, aluminum, and terbium.

3. The magnetic alloy material according to claim 1, wherein
a composition ratio of terbium is equal to or more than 5 atomic percent and equal to or less than 20 atomic percent in three elements of iron, aluminum, and terbium.

4. The magnetic alloy material according to claim 1, wherein
a composition ratio of iron, aluminum, and terbium is 6:2:1 in three elements of iron, aluminum, and terbium.

5. A thermoelectric conversion element, comprising
a power generation body including the magnetic alloy material according to claim 1, wherein
the power generation body has a plate-like shape including two main surfaces facing each other, and the magnetic alloy material is magnetized in an in-plane direction of the two main surfaces.

6. A thermoelectric conversion element, comprising
a power generation body having a structure in which a first magnetic layer including the magnetic alloy material according to claim 1 and a second magnetic layer in which a spin Seebeck effect appears by application of a temperature gradient are laminated.

7. A thermoelectric conversion element, comprising
a power generation body formed of a magnetic network including the magnetic alloy material according to claim 1, and a magnetic particle that is dispersed inside the magnetic network and in which a spin Seebeck effect appears by application of a temperature gradient.

8. A thermoelectric conversion module, comprising
a power generation body having a pipe structure including the magnetic alloy material according to claim 1.

9. The thermoelectric conversion module according to claim 8, wherein
the power generation body having the pipe structure is magnetized in a circumferential direction centered on a pipe axis.

10. The thermoelectric conversion module according to claim 8, further comprising
at least two electrode terminals disposed at an interval along a pipe axial direction on an outer surface of the power generation body having the pipe structure.
